(19) United States
(12) Patent Application Publication
(10) Pub. No.: US 2026/0141970 A1
(43) Pub. Date: May 21, 2026

(54) Apparatus for High Bandwidth Memory

(71) Applicant: NEOWINE Co., Ltd., Seongnam-si (KR)

(72) Inventors: Hyo Seung LEE, Seongnam-si (KR); Choon Ho KIM, Seongnam-si (KR)

(21) Appl. No.: 19/257,292

(22) Filed: Jul. 1, 2025

(30) Foreign Application Priority Data
Nov. 21, 2024 (KR) 10-2024-0166903
May 21, 2025 (KR) 10-2025-0065944
Jun. 2, 2025 (KR) 10-2025-0071973

(51) Int. Cl. G11C 29/44

(52) U.S. Cl. CPC G11C 29/44

(57) ABSTRACT

An apparatus for the high-bandwidth memory is disclosed. The Apparatus comprises; a plurality of high-bandwidth memory dies; a plurality of TSVs (Through-Silicon Via) each corresponding one-to-one with the high-bandwidth memory dies; a memory control module connected to the plurality of TSVs; a test module configured to detect defects in the high-bandwidth memory dies and TSVs; and a non-volatile memory configured to store defect location information of at least one faulty high-bandwidth memory die and at least one faulty TSV detected by the test module. The memory control module is configured to set the TSVs based on the fault location information stored in the non-volatile memory, thereby minimizing the complexity of path configuration even in cases where faulty high-bandwidth memory dies and their corresponding TSVs exist, enabling efficient handling of clustered faults, and maintaining the performance of clock synchronization.

### CROSS-REFERENCE TO RELATED APPLICATIONS

This application claims priority under 35 U.S.C. § 119 to Korean Patent Application No. 10-2024-0166903, filed on Nov. 21, 2024, Korean Patent Application No. 10-2025-0065944, filed on May 21, 2025, and Korean Patent Application No. 10-2025-0071973, filed on Jun. 2, 2025 in the Korean Intellectual Property Office, the entire contents of which are incorporated herein by reference.

### BACKGROUND OF THE INVENTION

### Field of the Invention

The present invention relates to an apparatus for high bandwidth memory (HBM), and more particularly, to an apparatus capable of operating by isolating a faulty HBM die and its one-to-one corresponding through-silicon via (TSV).

### Brief Description of the Related Arts

In general, HBM memories often experience initial faults or progressive faults due to the stacking of multiple silicon dies in a small area. GPGPU cards exhibit a progressive failure rate of approximately 1.3%, with 0.9% arising from the SoC and 0.4% from the HBM memory interface process.

To date, once semiconductors are shipped, there is no available method to detect or handle progressive failures that occur during operation. As semiconductor fabrication processes have become increasingly miniaturized, such as through the adoption of EUV lithography, the number of transistors has approached one trillion. In these ultra-fine circuits, issues that were previously negligible—such as radiation-induced circuit destruction and increased power consumption—are now causing serious problems, including heat generation in GPGPUs, transistor failure, and memory cell damage.

The error rate in deep learning computations caused by GPGPU faults is approaching 0.4%. Ultimately, there is a need for a method that addresses both yield degradation and progressive fault issues in HBM by isolating the faulty portions in hardware and software, thereby preventing such faults from affecting the operation of the HBM.

### SUMMARY OF THE INVENTION

According to an aspect of the disclosure, there is provided an apparatus for high bandwidth memory (HBM) comprising: a plurality of high bandwidth memory dies (HBM dies); a plurality of through-silicon vias (TSVs), each corresponding one-to-one to the plurality of HBM dies; a memory controller module conFigureured to control connections between the plurality of HBM dies and the plurality of TSVs; a test module configured to detect faults in the plurality of HBM dies and the plurality of TSVs; and a non-volatile memory configured to store fault locations of at least one faulty HBM die and at least one faulty TSV detected by the test module, wherein the memory controller module is configured to establish connections to the TSVs corresponding to the fault locations stored in the non-volatile memory,

In some embodiments, the test module is configured to operate when the apparatus is booted up, operate periodically at predefined time intervals, or operate in response to a control command, and to store fault locations of the HBM dies and the TSVs in the non-volatile memory based on the outcome of the test module operation.

In some embodiments, the memory controller module is configured to operate when the apparatus is booted up, periodically at predetermined intervals, or in response to an operation command,
and, when a TSV corresponding to a fault location stored in the non-volatile memory is present, to set an operation for the TSV corresponding to the fault location.

In some embodiments, the memory controller module is configured to isolate the TSV corresponding to the fault location stored in the non-volatile memory so as to exclude it from operation, and the apparatus for high bandwidth memory operates excluding the corresponding TSV based on the setting by the memory controller module.

In some embodiments, the memory controller module is configured to set at least one TSV corresponding to the fault location stored in the non-volatile memory to be excluded either by turning off power to the TSV in hardware, or by making the corresponding TSV inactive in software as if it does not exist.

In some embodiments, the memory controller module is configured to exclude all HBM dies and TSVs corresponding to the fault locations stored in the non-volatile memory from operation when they are multiple.

In some embodiments, the said non-volatile memory includes information on the plurality of HBM dies and the TSVs corresponding respectively to each of the HBM dies, includes individual information on each HBM die and corresponding TSV, and includes information indicating the number of faults for each faulty TSV.

In some embodiments, the test module includes a Memory Built-In Self-Test (MBIST) module.

In some embodiments, the apparatus includes the at least one redundant HBM die and the same number of redundant TSVs corresponding one-to-one to the at least one redundant HBM die.

In some embodiments, the memory controller module is configured to isolate at least one TSV corresponding to the fault location stored in the non-volatile memory so as to exclude it from operation of the apparatus, and to connect the same number of TSVs from among the redundant TSVs in place of the excluded TSVs so as to include them in the operation of the apparatus.

In some embodiments, the memory controller module is connected to the TSVs in the following order—an I/O channel, a 2-channel multiplexer, a TSV, and an HBM die.

In some embodiments, the connection to the TSV of the 2-channel multiplexer is reconfigured under the control of said memory controller module.

In some embodiments, the connection to the TSV of the 2-channel multiplexer is reconfigured in response to a control signal applied to the 2-channel multiplexer.

In some embodiments, when one redundant high bandwidth memory die and one redundant TSV corresponding one-to-one to the redundant high bandwidth memory die are provided,
said memory controller module is configured to disconnect the connection to the TSV at the fault location in the corresponding 2-channel multiplexer stored in the non-volatile memory,
sequentially connect to the next TSV,
and connect to the one redundant TSV in the final 2-channel multiplexer.

In some embodiments, when a plurality of TSVs corresponding to fault locations stored in the non-volatile memory are present,
said memory controller module is configured to disconnect and exclude from operation the TSVs corresponding to more than one of the detected fault locations, and is configured to operate while excluding the corresponding TSVs.

In some embodiments, when a plurality of redundant high bandwidth memory dies and a corresponding plurality of redundant TSVs, each in a one-to-one correspondence with the redundant high bandwidth memory dies, are provided, said memory controller module is configured to sequentially disconnect connections to a plurality of TSVs corresponding to fault locations stored in the non-volatile memory in the respective 2-channel multiplexers, to sequentially connect to subsequent TSVs, and to connect, in the final 2-channel multiplexer, to the plurality of redundant TSVs.

In some embodiments, when the number of TSVs corresponding to fault locations stored in the non-volatile memory exceeds the number of the plurality of redundant TSVs,
said memory controller module is configured to disconnect and exclude from operation the TSVs corresponding to the fault locations that exceed the plurality of redundant TSVs,
and is configured to operate while excluding the corresponding TSVs.

In some embodiments, the said 2-channel multiplexer is configured to connect to either a first channel or a second channel based on an input signal.

In some embodiments, the said 2-channel multiplexer is configured to connect to either the first channel or the second channel in both forward and reverse operation modes, based on an input signal.

The above and other aspects of the present disclosure will become more apparent to those skilled in the art from the following detailed description of the example embodiments with reference to the accompanying drawings.

### BRIEF DESCRIPTION OF THE DRAWINGS

FIG. 1 illustrates a configuration diagram of an apparatus for high bandwidth memory according to an embodiment of the present invention.

FIG. 2 illustrates a configuration diagram of another embodiment of an apparatus for high bandwidth memory according to the present invention.

FIG. 3 illustrates a conventional recovery method from FTSV to RSTV.

FIG. 4 illustrates a TBIST result layout in NVM.

FIG. 5 illustrates a structure of HBM Die with a Redundant HBM.

FIG. 6 illustrates a data output structure to TSV port.

FIG. 7 illustrates a data input structure from TSV port.

FIG. 8 illustrates a MUX structure for remapping faulty die addresses to redundant ones.

FIG. 9 illustrates a proposed method with Clock.

FIG. 10 illustrates a conventional method with difficult Clock control.

FIG. 11 illustrates a MUX connection architecture from DATA I/O channel to TSV group.

FIG. 12 illustrates a MUX connection architecture from TSV group to DATA I/O channel.

FIG. 13 illustrates a MUX connection architecture from DATA I/O channel to TSV group for FTSV bypass.

FIG. 14 illustrates a flowchart of MUX connection from DATA I/O channel to TSV group for FTSV bypass.

FIG. 15 illustrates a MUX connection architecture from TSV group to DATA I/O channel for FTSV bypass.

FIG. 16 illustrates a flowchart of MUX connection from TSV group to DATA I/O channel for FTSV bypass.

### DETAILED DESCRIPTION

Hereinafter, embodiments of the present invention will be described in detail with reference to the accompanying drawings so that those skilled in the art can easily carry out the invention. The present invention may be implemented in various different forms and is not limited to the embodiments described herein.

To clearly describe the present invention, parts irrelevant to the description are omitted, and the same or similar components are denoted by the same reference numerals throughout the specification.

Throughout the specification, when a part is described as being “connected” to another part, this includes both “directly connected” and “electrically connected” via another element in between. Also, when a part is described as “comprising” an element, unless explicitly stated otherwise, it does not exclude the presence of other elements and may further include other elements.

When a part is described as being “above” another part, it may be directly above or have other parts in between. In contrast, when a part is described as being “just above” another part, no other part is interposed between them.

The terms such as “first,” “second,” and “third” may be used to describe various elements, components, regions, layers, and/or sections, but are not limited thereto.

These terms are used merely to distinguish one element, component, region, layer, or section from another, and do not imply any particular order or limitation. Accordingly, a “first” part, component, region, layer, or section described below may also be referred to as a “second” part, component, region, layer, or section without departing from the scope of the present invention.

The terminology used herein is merely for the purpose of describing particular embodiments and is not intended to limit the invention. The singular forms include the plural forms as well unless the context clearly indicates otherwise. The term “comprising” as used herein specifies the presence of stated features, regions, integers, steps, operations, elements, and/or components but does not preclude the presence or addition of one or more other features, regions, integers, steps, operations, elements, and/or components.

Relative spatial terms such as “below” and “above” may be used to more easily describe relationships of one element to another as shown in the drawings. These terms are intended to encompass both the meanings depicted in the drawings and alternative meanings or functions as understood in the context of the device in use. For example, if the device in the drawings is flipped, parts described as “below” other parts would then be “above” the other parts. Thus, the illustrative term “below” can encompass both upward and downward directions. The device may be rotated 90 degrees or at other angles, and the relative spatial terms shall be interpreted accordingly.

Unless otherwise defined, all terms used herein including technical and scientific terms have the same meaning as commonly understood by those skilled in the art to which this invention belongs. Commonly used terms that are defined in generally available dictionaries shall be interpreted as having meanings that are consistent with their use in the relevant technical field and the context of the present disclosure, and are not to be interpreted in an idealized or overly formal sense unless explicitly so defined.

Hereinafter, with reference to the accompanying drawings, an embodiment of the present invention will be described in detail to enable those skilled in the art to easily carry out the invention. However, the present invention may be implemented in various different forms and is not limited to the embodiments described herein.

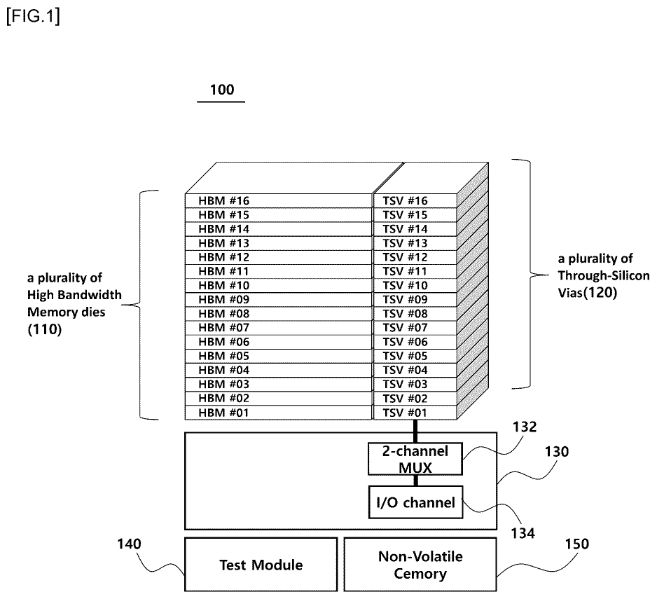

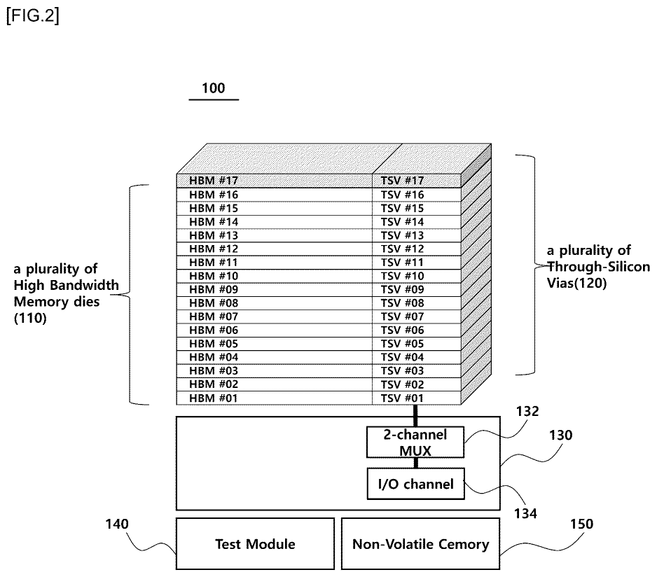

FIG. 1 is a configuration diagram of an apparatus for high bandwidth memory according to an embodiment of the present invention. FIG. 2 is a configuration diagram of another embodiment of an apparatus for high bandwidth memory according to the present invention.

Referring to FIG. 1, an apparatus for high bandwidth memory according to an embodiment of the present invention includes: a plurality of high bandwidth memory dies (HBM Die, 110); a plurality of through-silicon vias (TSVs, 120), each corresponding one-to-one with the plurality of HBM dies; a memory controller module 130 configured to control the connections between the plurality of HBM dies and TSVs; a test module 140 configured to detect faults in the plurality of HBM dies and the plurality of TSVs; and a non-volatile memory 150 configured to store the fault locations of at least one of the HBM dies and TSVs in which faults were detected by the test module, wherein the memory controller module 130 may be configured to establish connections to TSVs based on the fault location data stored in the non-volatile memory 150.

In the plurality of HBM dies 110, the HBM memory may be implemented in a manner that stacks a large number of silicon dies in a small area. The plurality of TSVs 120, each corresponding one-to-one with each of the plurality of HBM dies 110, may serve to transmit data and power signals to the HBM dies. Meanwhile, TSVs are inherently difficult to manufacture due to the need to form extremely fine holes, and are therefore prone to a high rate of fault s.

The test module 140 may be configured to detect faults in the plurality of high bandwidth memory dies 110 and the plurality of TSVs 120, and the non-volatile memory 150 may be configured to store fault locations of at least one of the high bandwidth memory dies 110 and at least one of the TSVs 120 in which faults are detected by the test module 140.

The memory controller module 130 may be configured to control the connections between the plurality of HBM dies 110 and the plurality of TSVs 120. In particular, the memory controller module 130 may be configured to establish connections with TSVs corresponding to the fault locations stored in the non-volatile memory 150.

The test module 140 may be configured to operate when the high bandwidth memory device 100 is booted up, periodically at predetermined intervals, or in response to an operation command, and may store, in the non-volatile memory 150, fault locations of the high bandwidth memory dies 110 and TSVs 120 based on the result of its operation. That is, the test module 140 is intended to detect faults in the high bandwidth memory dies 110 and TSVs 120 of the apparatus 100, and may be operated at boot-up, at predetermined time intervals, or, additionally, in response to a control command, as needed.

The memory controller module 130 may be configured to operate when the apparatus 100 is booted up, periodically at predetermined intervals, or in response to an operation command. When a TSV corresponding to a fault location stored in the non-volatile memory 150 is present, the memory controller module 130 may be configured to set an operation for the TSV corresponding to the fault location.

Similar to the test module 140, the memory controller module 130 may be configured to operate when the apparatus 100 is booted up, periodically at predetermined intervals, or, additionally, in response to an operation command, as needed. In particular, when a TSV corresponding to a fault location stored in the non-volatile memory 150 is present, the memory controller module 130 may be configured to set an operation for the TSV corresponding to the fault location. That is, the memory controller module 130 may be operated periodically or as needed to configure the operation of the TSV corresponding to the fault location, depending on the circumstances.

The memory controller module 130 may be configured to isolate a TSV corresponding to a fault location stored in the non-volatile memory 150, so as to exclude it from the operation of the apparatus 100. The apparatus 100 may operate with the corresponding TSV excluded, in accordance with the configuration set by the memory controller module 130. That is, the device may be configured to operate by entirely excluding the faulty TSV.

Meanwhile, the memory controller module 130 may be configured to exclude at least one TSV corresponding to a fault location stored in the non-volatile memory 150 either by turning off power to the TSV in hardware or by configuring the system to treat the corresponding TSV as non-existent in software. That is, the TSV may be isolated either by a hardware-based method or by a software-based method.

In addition, when a plurality of high bandwidth memory dies 110 and TSVs 120 corresponding to fault locations stored in the non-volatile memory (150) are present, the memory controller module 130 may be configured to exclude all of the corresponding memory dies and TSVs from operation. That is, the memory controller module 130 may be configured to entirely exclude both the high bandwidth memory dies and the TSVs from operation in order to maintain operational speed, even at the cost of reduced storage capacity in the apparatus 100.

The non-volatile memory 150 may include information about all of the plurality of high bandwidth memory dies 110 and the corresponding plurality of TSVs 120, as well as individual information for each memory die 110 and its respective TSVs 120. It may also include data indicating the number of faults detected for each faulty TSV.

The test module 140 may include an MBIST (Memory Built-In Self-Test) module. MBIST is a self-test circuit that automatically checks for anomalies by applying electrical signals to the TSVs and monitoring their responses. Typically, the MBIST is executed before shipment of the HBM chip or during system boot-up Referring to FIG. 2, in an embodiment of the present invention, the apparatus for high bandwidth memory may further include at least one redundant high bandwidth memory die, and the same number of redundant TSVs corresponding one-to-one with the at least one redundant high bandwidth memory die.

Here, the memory controller module 130 may be configured to isolate at least one TSV corresponding to a fault location stored in the non-volatile memory 150, thereby excluding it from operation of the high bandwidth memory device 100, and to configure a connection to the same number of redundant TSVs among the redundant TSVs, so that the high bandwidth memory device 100 may include the substituted TSVs in operation.

The memory controller module 130 may be connected to the TSVs in the order of the I/O channel 134, 2-channel MUX 132, TSVs 120, and the high bandwidth memory dies 110. Since the 2-channel MUX 132 is inserted between the I/O channel 134 and the TSVs 120, it may not degrade the CLOCK synchronization performance.

Under the control of the memory controller module 130, the connection to the TSV through the 2-channel multiplexer may be changed. The change in the connection to the TSV of the 2-channel MUX may be performed by inputting a control signal to the 2-channel MUX.

In an embodiment of the present invention, when one redundant high bandwidth memory die and one redundant TSV corresponding one-to-one to the redundant memory die are provided, the memory controller module 130 may be configured to disconnect the connection to a TSV at a fault location in the corresponding 2-channel multiplexer, sequentially connect to the next TSVs, and, in the final 2-channel multiplexer, connect to the one redundant TSV. That is, a faulty TSV may be isolated through sequential connection switching, and a connection may be established to the one redundant TSV located at the end. In other words, in order to maintain the operating speed of the apparatus 100, the memory controller module (130) may be configured to entirely exclude one faulty high bandwidth memory die and its corresponding TSV from operation.

Meanwhile, when a plurality of TSVs corresponding to fault locations stored in the non-volatile memory 150 are present, the memory controller module 130 may be configured to disconnect and exclude from operation the TSVs corresponding to more than one of the detected fault locations. That is, for TSVs exceeding one in number, the device may be configured to operate while excluding them, even if this results in reduced storage capacity of the apparatus 100.

In another embodiment of the present invention, in an apparatus for high bandwidth memory (HBM), when a plurality of redundant high bandwidth memory dies are provided along with a corresponding plurality of redundant TSVs in a one-to-one correspondence with the redundant dies, the memory controller module 130 may be configured to sequentially disconnect connections to a plurality of TSVs corresponding to fault locations stored in the non-volatile memory 150 in the respective 2-channel multiplexers, sequentially connect to the next available TSVs, and, in the final 2-channel multiplexer, connect to the plurality of redundant TSVs.

The memory controller module 130 may be configured to disconnect and exclude from operation the TSVs corresponding to fault locations stored in the non-volatile memory when the number of such TSVs exceeds the number of available redundant TSVs, and to operate with the excess TSVs excluded.

The 2-channel MUX 132 may be configured to connect to either the first channel or the second channel according to an input signal. Furthermore, the 2-channel MUX 132 may be configured to switch between the first and second channels in both forward and reverse operational modes, depending on the input signal.

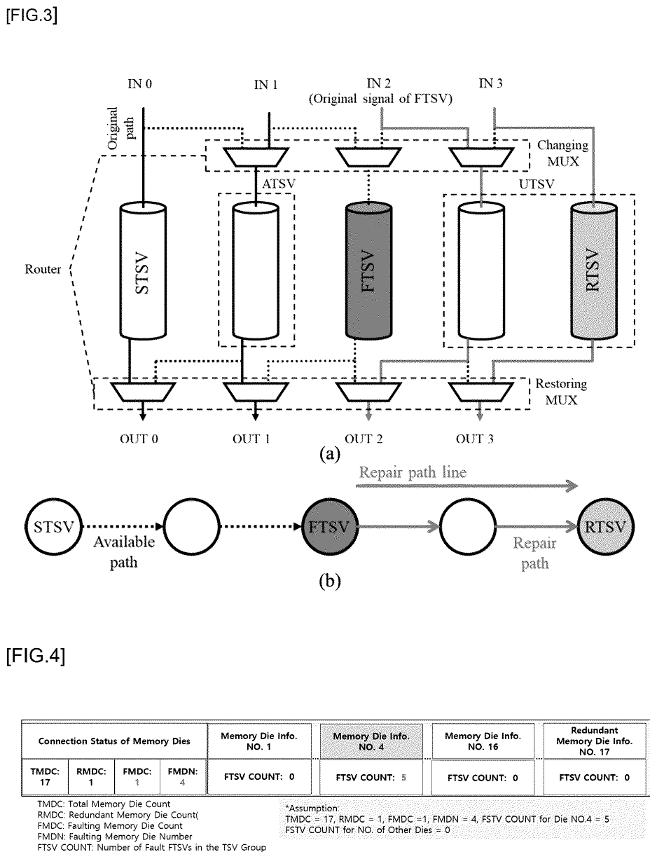

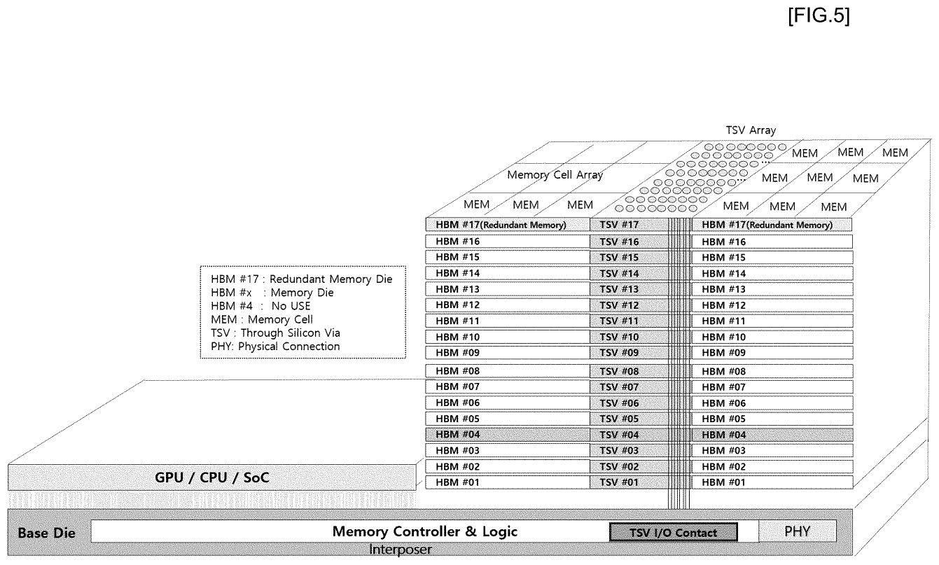

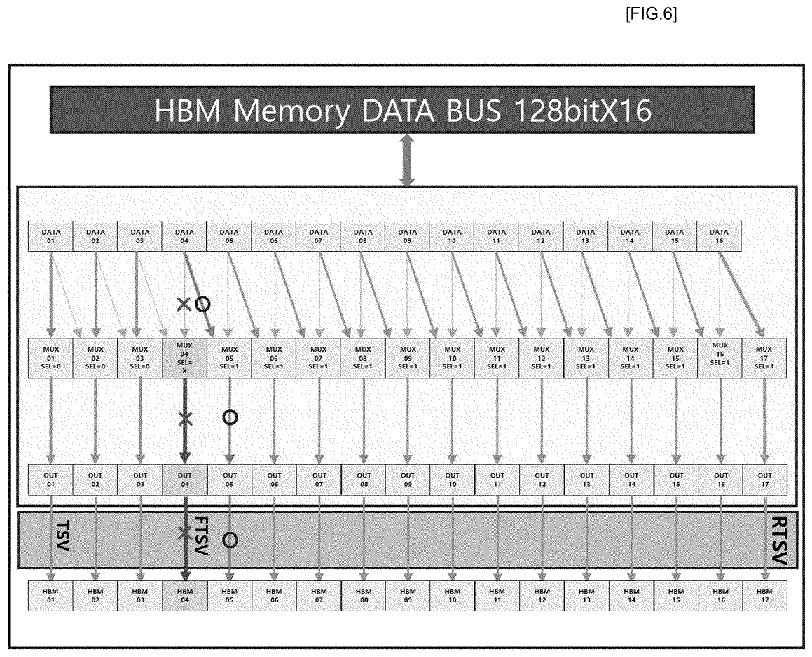

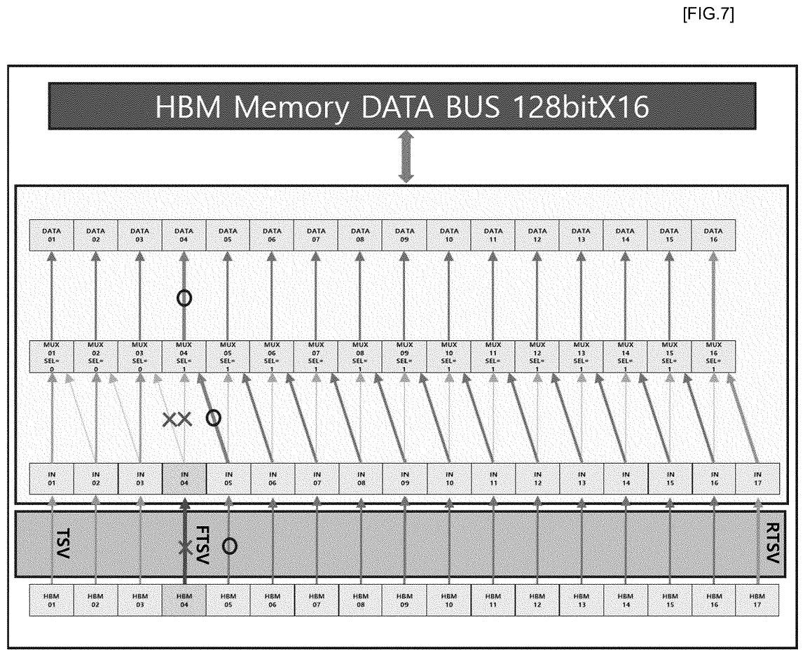

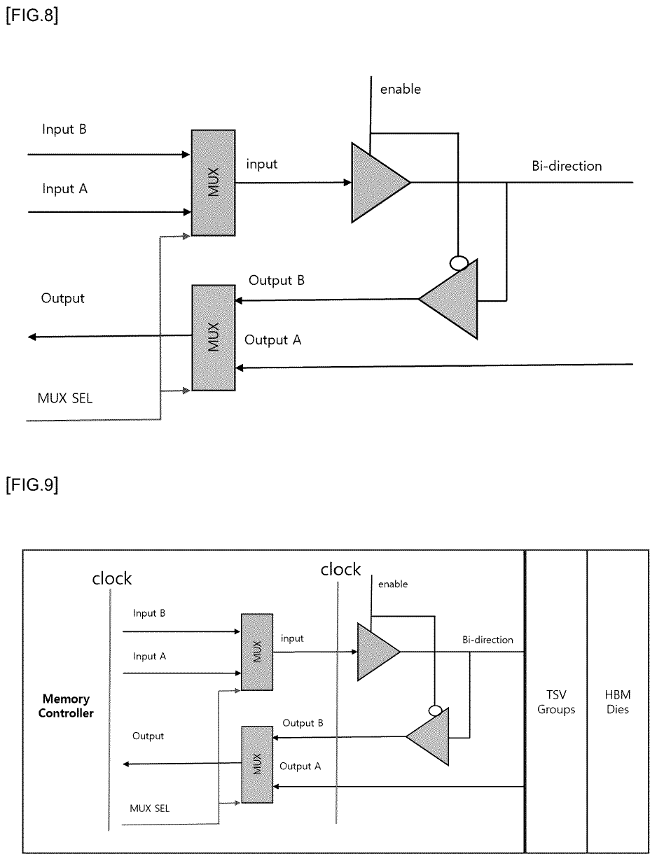

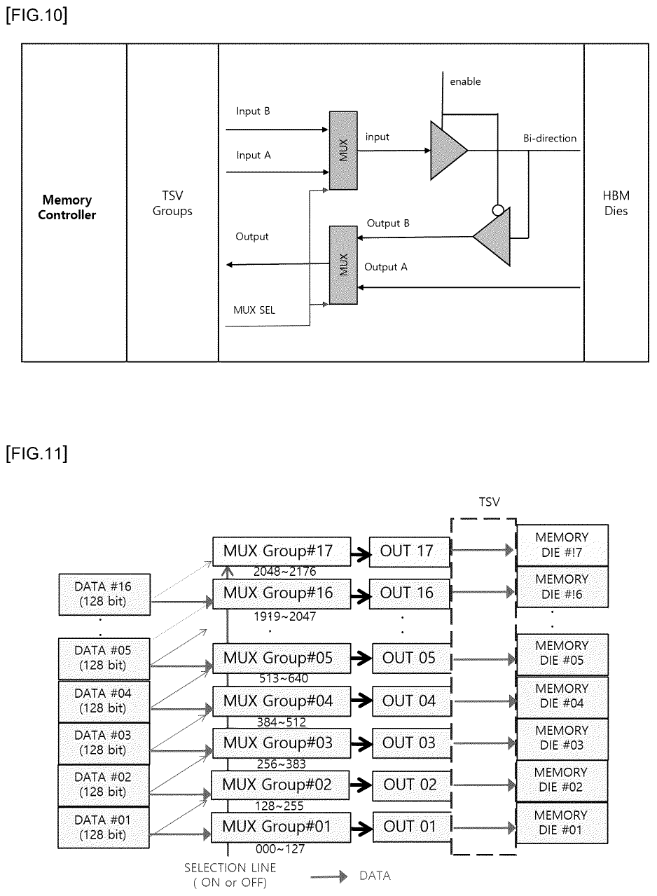

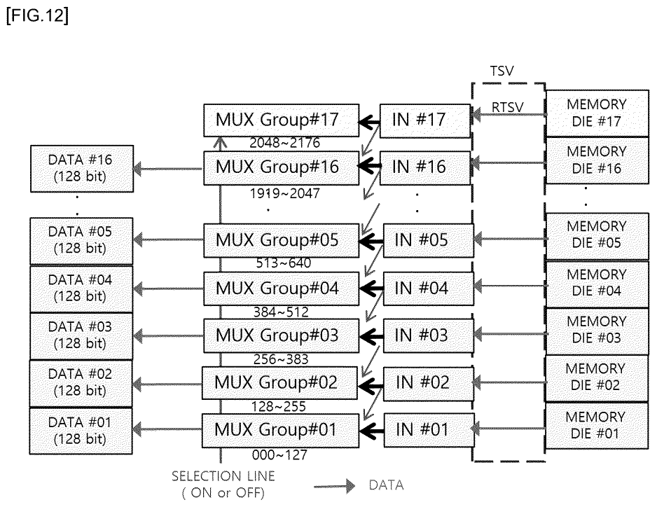

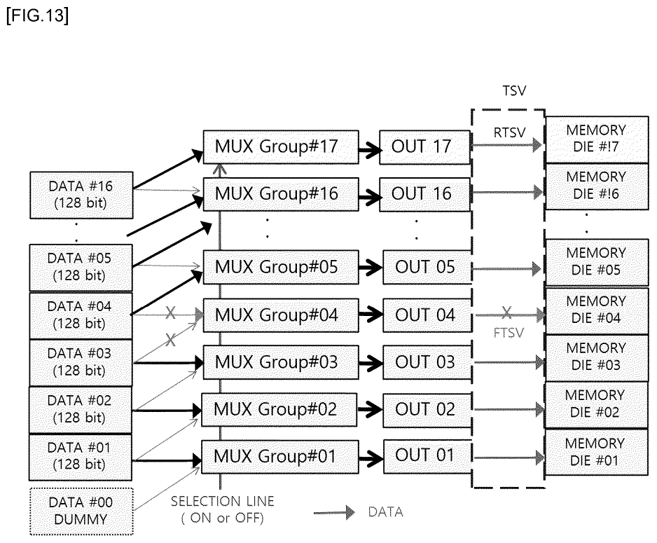

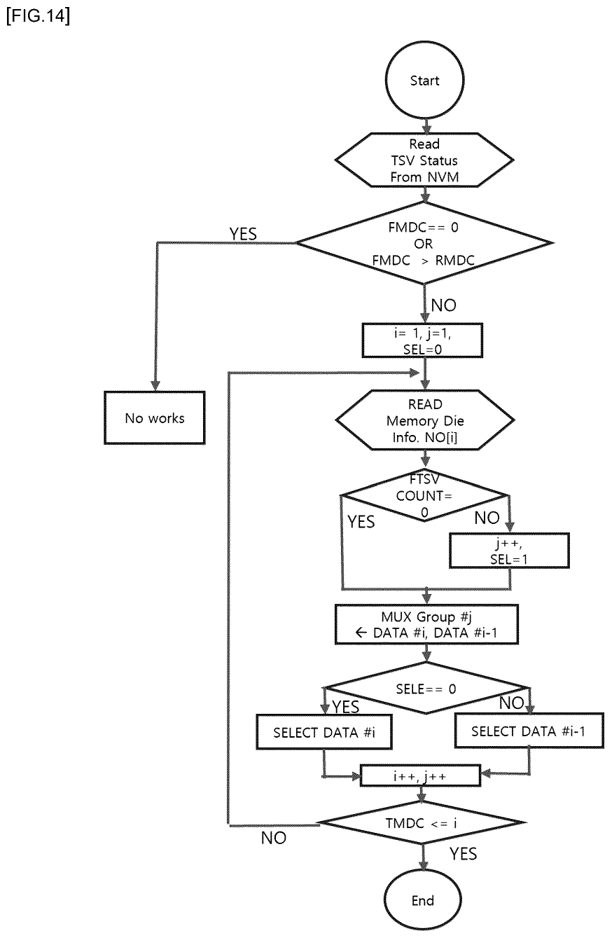

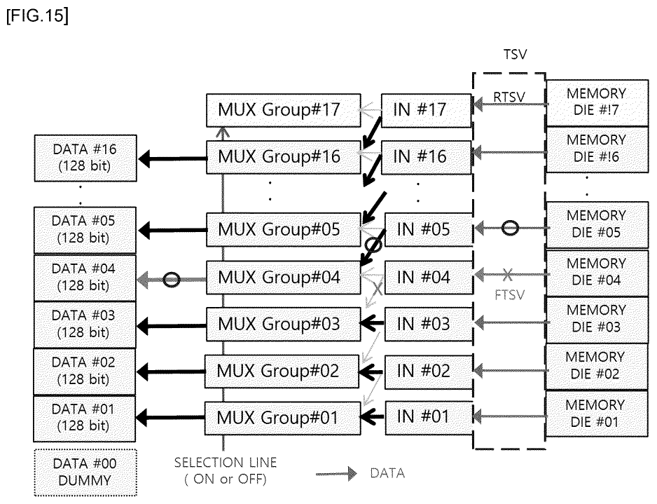

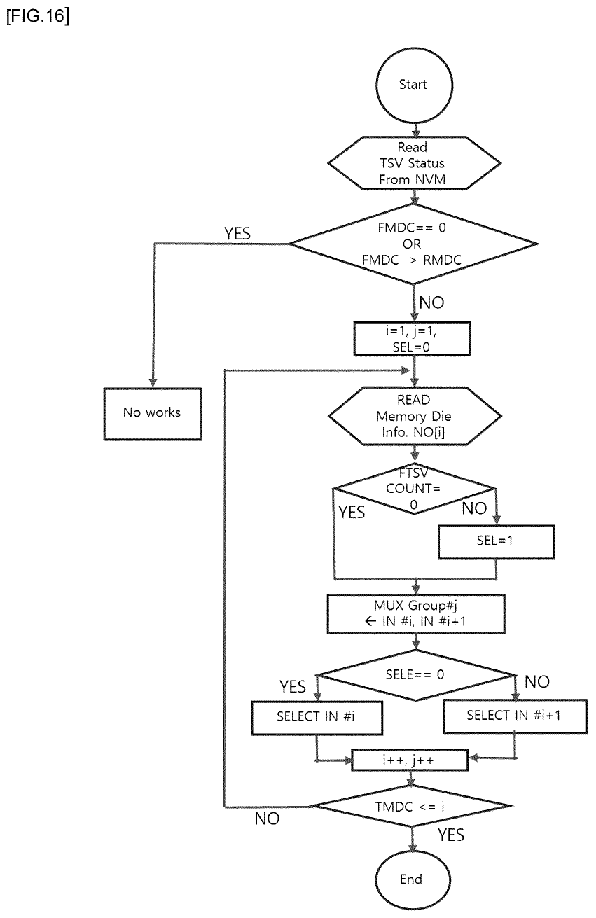

FIGS. 3 to 16 are diagrams for illustrating aspects of the embodiment according to the present invention. Specifically, FIG. 3 illustrates shows a conventional method of recovering FTSVs using RSTVs; FIG. 4 illustrates the TBIST result layout in the NVM; FIG. 5 illustrates the structure of an HBM die with a redundant HBM; FIG. 6 illustrates the data output structure to the TSV ports; FIG. 7 illustrates the data input structure from the TSV ports; FIG. 8 illustrates the MUX structure for remapping faulty die addresses to redundant ones; FIG. 9 illustrates the proposed invention with clock; FIG. 10 illustrates a conventional method with poor clock control; FIG. 11 illustrates the MUX connection architecture from the DATA I/O channel to the TSV group; FIG. 12 illustrates the MUX connection architecture from the TSV group to the DATA I/O channel; FIG. 13 illustrates the MUX connection architecture from the DATA I/O channel to the TSV group for FTSV bypassing; FIG. 14 illustrates a flowchart of the MUX connection from the DATA I/O channel to the TSV group for FTSV bypassing; FIG. 15 illustrates the MUX connection architecture from the TSV group to the DATA I/O channel for FTSV bypassing; and FIG. 16 illustrates a flowchart of the MUX connection from the TSV group to the DATA I/O channel for FTSV bypassing.

High Bandwidth Memory (HBM) implements a high-speed, high-capacity, and low-power memory system by vertically stacking dies and connecting data, control, and power signals through Through-Silicon Vias (TSVs). However, since TSVs are formed by drilling extremely fine holes, they are difficult to manufacture and have a high probability of defects, making them a major cause of yield reduction and reliability degradation in HBM.

As a general solution, when a Fault TSV (FTSV) is detected among the TSVs, a path reconfiguration technique is employed to bypass the faulty line through a pre-allocated Redundant TSV (RTSV), allowing data to flow normally. The RTSVs are included in the HBM design as spare TSVs in addition to those used for regular operation.

Although many studies have attempted to recover FTSVs, conventional methods often suffer from complex or inefficient recovery path algorithms, large area overhead in design, and difficulty recovering clustered faults (i.e., multiple faults located close together). In recovery architectures for FTSVs, paths are categorized into base paths (used when there are no faults in TSVs) and repair paths (used for FTSV recovery). When multiple FTSVs appear in various configurations within a single TSV group, the recovery path can become exceedingly complex.

In order to address these problems, the present invention disconnects the connection between the DATA I/O channel and the TSV group containing the fault TSVs (FTSVs), thereby preventing data from being transmitted to the corresponding memory die, and instead connects to a redundantly added REDUNDANT DIE for continued operation. Accordingly, in the present invention, the entire TSV group containing FTSVs can be bypassed via a simple recovery path using a multiplexer (MUX) included in the memory controller. As a result, even when multiple FTSVs occur within a single TSV group, there is no need to consider complex recovery path configurations.

Moreover, because the recovery path logic is implemented in the LOGIC CONTROL region of the BASE die, CLOCK synchronization is achievable, thus eliminating issues related to DELAY TIME that may arise from passing through external MUX and DEMUX of the memory controller.

The present invention proposes a solution to the problem of having to discard the entire HBM due to faults—namely, Fault TSVs (FTSVs)—that occur in the TSV group connected to a specific high bandwidth memory (HBM) die, which is a major cause of yield reduction in HBM. The invention considers adding one redundant memory die to a configuration of sixteen memory dies in HBM4.

When an error (FTSV) occurs in a TSV connected to a specific memory die, the connection between the data channel (I/O group) and the memory die connected to the faulty TSV group is disconnected, and the data channel (I/O group) is remapped to a functional memory die and the redundant memory die (r=1). Although this method requires the addition of one redundant memory die, it provides a fundamental solution to problems in existing methods, such as HBM yield degradation due to FTSV and time delays caused by MUX combinational logic.

In an HBM structure, DRAM dies are vertically stacked, and data/address/control signals between dies or between a die and an interposer (or base die) are transmitted via TSVs. That is, I/O signals are input/output through TSVs, and TSVs serve as the channels through which I/O data and signals are transmitted. The I/O numbers correspond to the TSV group arrangement, and since each TSV is mapped to a specific I/O line, the I/O pin numbers in die design correspond one-to-one with the physical locations of the TSVs. In DRAM die design, aligning the physical positions of the I/O blocks with the TSV layout is essential to optimize signal integrity and electrical performance. Accordingly, the I/O numbering is closely related to the TSV placement order. In FTSV repair and similar operations, the TSV number is treated as the I/O number. Furthermore, in fault-tolerant designs within the TSVs, such as BISR (Built-In Self Repair), it must be possible to remap a faulty I/O signal to another TSV. Therefore, consistent management of TSV identifiers and I/O numbers is required.

Because HBM transmits data through TSVs, a problem in a TSV prevents data from reaching the associated memory. As TSVs are extremely fine holes fabricated with high precision, the fault rate is high, and such faults are a major factor in determining HBM yield. Recently developed TSV densities have reached up to 10,000 per mm² (10 k/mm²), and efficient testing and detection of FTSVs (Fault TSVs) is critical. To identify FTSVs, a TSV Built-In Self-Test (TBIST) is required. TBIST automatically applies electrical signals to TSVs and verifies the response to detect abnormalities. Typically, TBIST is performed before shipment or during booting of the HBM chip. The criterion for identifying an FTSV (Fault TSV) is whether the test result deviates from the expected normal signal.

Conventional TSV recovery architectures face significant challenges in handling FTSVs, particularly when the FTSVs are clustered. These challenges include low recovery rates, large area overhead, long signal delays, or recovery mechanisms that are only applicable in limited cases.

FIG. 3 illustrates a conventional method in which a predetermined number of Redundant TSVs (RTSVs) and paths replacing corresponding FTSVs are preset within a TSV group. If an FTSV occurs, recovery is performed by switching to the preset RTSV paths. The problem arises when multiple RTSVs exist in various TSV groups—this makes path planning complex. If the number of FTSVs exceeds the available RTSVs, recovery becomes impossible.

Therefore, if multiple FTSVs exist within the TSV range connected to a memory die, a complex recovery path is required. Studies show that recovering a single FTSV in such cases adds approximately 40 ps of delay. Furthermore, prior methods require inserting routers (MUXes) between TSVs and HBM dies, introducing hardware overhead and making CLOCK synchronization more difficult.

In the method proposed in the present invention, the status (normal or faulty) of all TSVs connected to the memory (memory banks) of the HBM is checked using TBIST (TSV Built-in Self-Test), and the information is recorded in the NVM. Based on that information, recovery operations for FTSVs (Fault TSVs) are carried out. TBIST is conducted during chip shipment and system booting. If any FTSV is detected among the total TSVs, the failure information is recorded by TSV group (or I/O channel) that connects to the memory die (memory bank) in the “TSV Status Register for TBIST” within the NVM.

The structure is illustrated in FIG. 4. As shown in FIG. 4, the results of the TBIST are managed on a per I/O channel basis for each memory die (e.g., each high bandwidth memory die is connected via 128 TSVs). The TSV connection status is recorded as both overall statistics for all high bandwidth memory dies and individual status information for each die.

In the overall statistics region labeled “Connection STATUS of Memory Dies,” the following information is recorded: the total number of high bandwidth memory dies (TMDC), the number of redundant memory dies (RMDC), the number of faulty memory dies (FMDC), and the identification numbers of the faulty memory dies (FMDN).

In each per-die section labeled “Memory Die Information No. x,” the number of FTSVs (FTSV COUNT) detected in the TSV group connected to the corresponding die is recorded.

After TBIST is performed, if no FTSVs are detected in any of the TSV groups connected to the memory dies, the FMDC value is set to ‘0’. However, if at least one FTSV is present, the FMDC stores the number of memory dies in which FTSVs are detected, and the corresponding “Memory Die Info. NO. #” field records the number of FTSVs in the FTSV COUNT entry.

In the example shown in FIG. 4, the assumed values are as follows: TMDC=17, RMDC=1, FMDC=1, and FMDN=4, indicating that five FTSVs are detected in the fourth high bandwidth memory die.

When the FMDC value is greater than or equal to 1 in the TBIST result, this triggers a remapping process in which the connection to the memory die previously connected to the TSV group containing the FTSVs is disconnected, and the connection is switched to the redundant memory die.

In the present invention, one redundant memory die and a redundant TSV group (e.g., consisting of 128 TSVs) for delivering data to the redundant memory die are additionally included in the HBM4 structure. When an FTSV occurs within the TSV range of a specific channel connected to an HBM die, the connection to that TSV group is disconnected, and the memory die connected to the faulty TSV group is bypassed. Data I/O is then remapped to the redundant memory die, and the system is designed to have the structure shown in FIG. 5 to enable this process.

FIG. 5 illustrates an HBM4 configuration with 16 HBM dies and one added redundant HBM die, resulting in a total of 17 TSV groups for connecting to each memory die.

FIG. 6 is based on an HBM4 configuration with 16 memory dies and shows an example in which HBM #17 is added as a redundant memory die, and an FTSV has occurred in the TSV group connected to HBM #04.

The present invention is based on the concept of identifying the TSV status of the HBM from the non-volatile memory (NVM) register, such as that shown in FIG. 4, which stores the results of the TBIST. When an FTSV is detected, the connection to the TSV group in which the FTSV occurred is disconnected, and a new connection is made to the TSV group associated with the redundant memory.

FIG. 6 illustrates a structure in which, when an FTSV is detected in the TSV group connected to Memory Die #4 (HBM 04) as a result of TBIST, the connection between the TSV group containing the FTSV and the data bus is disconnected via a multiplexer (MUX), and a new connection is made to the RSTV group, thereby enabling the use of the redundant memory.

FIG. 7 illustrates the concept of reading data from the redundant memory and routing it to the data bus while bypassing the TSV group where the FTSV is present.

FIGS. 6 and 7 are based on the HBM4 configuration, where each channel from DATA01 to DATA16 (each channel consisting of two sub-channels) has 128 I/Os—two 64-bit sub-channels. The I/O line range for each channel is 128. This mapping structure is defined in the JEDEC JESD271-4 HBM4 Bump Matrix Spreadsheet.

The present invention improves HBM yield by placing multiplexers (MUXs) between the I/O channels and the TSV groups such that, when transferring data from the data I/O channels to the HBM, TSV groups (each consisting of 128 TSVs) containing FTSVs can be bypassed, and the data can instead be routed through an RTSV group to a redundant die.

As shown in FIG. 6, transferring data from the data bus I/O channels to the HBM side requires 17 MUX groups, each consisting of 128 MUXs. Conversely, to read data from the HBM and send it to the data bus I/O channels, 16 MUX groups, each also composed of 128 MUXs, are used.

The proposed method configures 17 bidirectional MUX groups. When writing data from the data bus I/O channels to the HBM, all 17 MUX groups are used. When reading data from the HBM to the data bus I/O channels, only 16 MUX groups are used.

Since the HBM memory data I/O bus is configured such that each channel consists of 128 bits (two 64-bit sub-channels), one MUX group is formed using 128 2×1 multiplexers per I/O bus channel. When a fault is detected in the BIST results indicating the presence of one or more FTSVs, the connection to the MUX group associated with the TSVs containing the FTSVs is disabled, and the connection is re-routed to the next MUX group connected to an upper-layer high bandwidth memory die.

In the present invention, HBM4 is used as an example. In HBM4, each data channel is connected to a corresponding MUX group that transfers data to TSVs through 128 2×1 multiplexers. Assuming a stack of 16 memory dies and one redundant memory die, the HBM memory data bus is composed of 128-bit×16 channels. Accordingly, 16 MUX groups are used for normal operation, and one additional MUX group is provided to support bypassing, resulting in a total of 17 MUX groups.

In the present invention, each MUX receives data inputs from two channels. For the MUX groups connected to the TSV groups prior to the occurrence of an FTSV, a selection signal (SEL) of ‘0’ is applied. For the MUX group connected to the TSV group where the FTSV has occurred and all subsequent MUX groups, a selection signal (SEL) of ‘1’ is applied.

Depending on whether the SEL signal is ‘0’ or ‘1’, the MUX selects one of the two input data channels and forwards the selected data accordingly. This allows the system to bypass the TSV group containing the FTSV and shift the data path to connect with the redundant memory die through the RTSV group.

In FIGS. 6 and 7, a 2×1 multiplexer, as illustrated in FIG. 8, is used to remap the addresses between the data bus I/O channel ports and the TSV group I/O ports. FIG. 8 shows a bidirectional 2×1 MUX that receives two inputs (Input A and Input B, or Output A and Output B), and selects one of them based on the signal on the select line (SEL).

To transfer data from the data bus to the HBM side, Input A and Input B serve as inputs. When the MUX SEL signal is ‘0’, Input A is selected; when the SEL is ‘1’, Input B is selected.

Conversely, to read data from the HBM and transmit it to the memory data bus, as shown in FIG. 8, Output A and Output B are provided as inputs. When the MUX SEL signal is ‘0’, Output A is selected; when it is ‘1’, Output B is selected.

In the present invention, the 128-bit data received through each data bus I/O channel is assigned to a MUX group consisting of 128 MUXs, and each bit of data is input to a corresponding MUX. At this point, based on the value of the SELECT LINE, the same input—either “A” or “B”—is selected for all 128 MUXs. That is, when the MUX SEL signal is ‘0’, the “A” line is selected, and when the signal is ‘1’, the “B” input is selected as the output.

As shown in FIG. 9, in the present invention, the 128-bit data received through each data bus I/O channel is assigned to a MUX group, the MUXs are implemented within the memory controller logic located in the base die. This allows control over the clock and enables delay time synchronization even after passing through the MUXs.

However, in conventional FTSV repair methods, as shown in FIG. 10, the MUX is inserted between the TSV group and the high bandwidth memory die. This structure makes it difficult to implement clock control, and thus, it becomes challenging to maintain proper synchronization.

In the present invention, the architecture for connecting the MUX between the data I/O channel and the TSV group is configured as shown in FIG. 11, while the architecture for connecting the MUX from the TSV group to the data I/O channel is configured as shown in FIG. 12.

Under normal operating conditions, in the absence of FTSVs, data is transmitted from the data I/O channel through the MUX group and TSV group to the high bandwidth memory die, following the data path illustrated in FIG. 11. Conversely, when reading data from the HBM memory, the data is transmitted from the memory die through the TSV group and MUX group to the data I/O channel, following the data path illustrated in FIG. 12.

Each TSV group, based on the HBM4 standard, consists of 128 TSVs, and TSV numbers are assigned sequentially in ranges of 128 per group starting from 0. That is, TSV GROUP #1 covers TSV numbers 0 to 127, and each subsequent TSV group is assigned TSV numbers in increments of 128. Accordingly, the data-dedicated TSV range in HBM4 is generally managed using TSV numbers from 0 to 2047.

In the present invention, the RTSVs required for connection to the redundant memory die (HBM #17) are assigned TSV numbers 2048 through 2175, forming a separate TSV group for management purposes.

When the result of the TBIST, performed either at the time of shipment or during boot-up, indicates the presence of an FTSV, the system initiates a repair process based on the concept of remapping the address by bypassing the MUX group connected to the TSV group where the FTSV occurred, and connecting to the next MUX group.

The repair algorithm is described in two cases: (1) when transmitting data from the data I/O bus to the high bandwidth memory die through the TSV group (Send data to HBM), and (2) when reading data from the high bandwidth memory die through the TSV group and delivering it to the data I/O bus (Read data from HBM).

### (1) Send Data to HBM

The architecture for transmitting data to HBM when an FTSV exists is shown in FIG. 13. The algorithm is designed to identify which TSV group contains the FTSV and to bypass the MUX group connected to that TSV group. In FIG. 13, an FTSV occurs in the TSV group connected to the 4th MUX group.

In the present invention, a data channel (128 bits) is mapped to a MUX group (consisting of 128 MUXs) as illustrated in FIG. 13. Each of the 128 MUXs that constitute a MUX group receives two inputs and selects one of them as the output based on the signal (0 or 1) applied to the selection line.

In the example shown in FIG. 13, an FTSV is detected in the TSV group connected to the fourth MUX group. To avoid the faulty TSV group, a signal of ‘0’ is applied to the selection line of the first through third MUX groups to select input A, while a signal of ‘1’ is applied to the fourth through seventeenth MUX groups in order to select input B and route the data to the Redundant Die.

The mechanism for connecting from the data I/O channel to available TSV groups while bypassing FTSVs is illustrated in FIG. 14 and explained in Algorithm 1.

[Algorithm 1: Send data to HBM]

\textcircled{1} Read TSV status in TBIST result from NVM.
\textcircled{2} IF FMDC == 0 || FMDC > RMDC go to the NO work(Stop).
\textcircled{3} Initialize variable i, j and SEL.
(i, j =1; SEL =0;)
\textcircled{4} Read the information of the i-th memory die.
\textcircled{5} IF (FTSV COUNT > 0) SEL = 1, j++;
\textcircled{6} Connect the i-th DATA I/O bus and the (i−1)-th DATA I/O bus to the
j-th MUX group.
(MUX Group#j <− DATA #i, DATA #i−1;)
\textcircled{7} SEL == 0 THEN DATA #i;
ELSE SELECT DATA #i−1;
\textcircled{8} Increment the values of variables i and j by 1.
(i++, j++;)
\textcircled{9} TDMC <= i then goto END(STOP)
else goto \textcircled{4}

Algorithm 1 performs the function of reading the TBIST results from the NVM to identify the status of all TSVs connected to the HBM, and reroutes connections through the MUX groups by excluding the TSV group in which an FTSV has occurred and connecting to a redundant memory die via the pre-assigned RTSVs.

In Step \textcircled{3} of the algorithm, the variable iis shared to represent both the memory die information block number and the data I/O channel number. The variable jis used to indicate the MUX group number, and SELis used to select one of the two inputs of the MUX.

Based on the status of the TSVs connected to the memory die, for MUX groups from the first one onward, the data corresponding to the index matching the MUX number is selected. However, if an FTSV is detected in a given TSV group, the corresponding MUX group is skipped, and from the next MUX group onward, the data one index lower than the MUX number is selected. This is achieved by incrementing the MUX group number by one and setting the select signal (SEL) to ‘1’, thereby ensuring that the MUX selects data at an index one less than the current MUX number.

(2) Read Data from HBM

FIG. 15 illustrates the architecture used to transmit data from the HBM to the data I/O bus when an FTSV is present. Similar to case (1), the proposed algorithm identifies in which TSV group the FTSV has occurred among the total TSV groups and configures the logic such that the MUX group is not connected to the TSV group containing the FTSV.

In the example shown in FIG. 15, since an FTSV has occurred in the TSV group connected to the fourth high bandwidth memory die (HBM #4), the fourth die is rendered unusable. As a result, the TSV group containing the FTSV (i.e., the fourth TSV group) is bypassed, and the fifth TSV group connected to HBM die #5 is instead connected to the fourth MUX group.

In the present invention, when an FTSV is present, the structure of the TSV groups, MUX groups, and data I/O bus is mapped as shown in FIG. 15 to enable data to be read from the HBM and transmitted to the data I/O bus. Each MUX group consists of 128 MUXs, and each MUX receives two input signals, IN #n (n=1, 2, . . . , 17). Based on the signal (0 or 1) applied to the selection line (SEL), one of the two inputs is selected as the output.

In the example of FIG. 15, since an FTSV has occurred in the fourth TSV group, the fourth TSV group is bypassed. To do so, for the first through third MUX groups, the SEL signal is set to ‘0’ so that input A (corresponding to the i-th TSV group) is selected over input B (i+1-th TSV group).

For the fourth MUX group, the fifth TSV group—which is connected to the fifth high bandwidth memory die—is assigned, and the SEL signal is set to ‘1’ so that, from the fifth MUX group onward, each MUX group selects input B, corresponding to the (i+1)-th TSV group.

Accordingly, in the MUXs where the selection line is set to ‘0’, input A—corresponding to the i-th TSV group—is selected. From the fourth MUX group through the sixteenth MUX group, which are required to complete the connection to the final Redundant Die, the selection line is set to ‘1’, and input B—corresponding to the (i+1)-th TSV group—is selected.

The mechanism for establishing the MUX connection from the available TSV groups to the data I/O channel while bypassing the FTSV is illustrated in FIG. 16. The operational flow of this remapping is described in Algorithm 2.

[Algorithm 2: Read data from HBM]

```
\textcircled{1} Read TSV status in TBIST result from NVM.
\textcircled{2} IF FMDC == 0 || FMDC > RMDC go to the NO work(Stop)
\textcircled{3} Initialize variables i, j, and SEL
(i, j = 1; SEL = 0)
\textcircled{4} Read the information of the i-th memory die.
\textcircled{5} IF (FTSV COUNT > 0) SEL = 1
\textcircled{6} Connect the i-th DATA I/O BUS and (i−1)-th DATA
I/O BUS to the j-th MUX group
(MUX Group #j ← IN #i, IN #i+1)
\textcircled{7} If SEL == 0 THEN SELECT the IN #i;
    ELSE SELECT IN #i+1
\textcircled{8} Increment the values i and j by 1
    (i++, j++)
\textcircled{9} If TDMC ≤ i then goto END(STOP)
  else go to step \textcircled{4}
```

Algorithm 2 reads the TBIST results from the non-volatile memory (NVM) to determine the status of all TSVs connected to the HBM. Based on this information, any TSV group in which an FTSV (Faulty TSV) is detected is excluded from connection with its corresponding MUX group. The algorithm then establishes connections between the available TSV groups and MUX groups, enabling the use of the redundant memory die connected via the pre-assigned RTSV group.

In Step \textcircled{3} of the algorithm, the variable iis shared to indicate both the Memory Die Info block number and the data channel I/O number, while the variable jis used to designate the MUX group number. The SELsignal is used to select one of the two inputs of the MUX.

The algorithm examines the status of the TSVs connected to each memory die. For TSV Group #1 and subsequent groups without faults, the MUX selects the input IN #whose index matches that of the connected TSV group. If an FTSV is present in a particular TSV group, that group is excluded from connection. Starting with the MUX group that would have been connected to the faulty TSV group, the algorithm instead connects the next TSV group—i.e., the TSV group whose index is one greater than that of the originally mapped group—to the MUX group, and sets the SELsignal to ‘1’. This ensures that all subsequent MUX groups select the IN #corresponding to the TSV group whose index is one greater than that of the originally mapped group, thereby bypassing the faulty group.

HBM is a structure that vertically stacks dies and uses TSVs to achieve a high-speed, high-capacity, and low-power memory system, making TSVs a core technology. However, TSVs require extremely precise processing, making fabrication difficult and prone to faults, which are a major cause of reduced HBM yield and reliability. When an FTSV occurs, it can cause the entire memory stack to malfunction or result in a significant drop in yield, making fault detection and repair technologies critical.

The present invention proposes a method that eliminates the complexity caused by conventional repair path configuration and enables easy recovery even when multiple FTSVs (Faulty TSVs) appear in a clustered manner within a single TSV group. A comparative analysis is conducted between the conventional methods and the proposed method based on several key evaluation items.

The evaluation items are defined as follows:
\textcircled{1} Path Configuration Complexity: The complexity of the recovery path as the number of FTSVs within a TSV group increases and as the number of RTSVs required for repair also increases.
\textcircled{3} Clustered FTSV Tolerance: The ability of the method to accommodate scenarios in which the number of FTSVs occurring in a single TSV group exceeds the number of available RTSVs.
\textcircled{3} Clock Synchronization: Whether delay time is introduced when repairing FTSVs due to clock synchronization issues.

| | | The method according to |
|---|---|---|
| Evaluation Items | Conventional Method | the present invention |
| Path Configuration | High | Low |
| Complexity | | |
| Clustered FTSV | Weak | Strong |
| Tolerance | | |
| Clock Synchronization | Impossible | Possible |

From the perspective of path configuration complexity (\textcircled{3}), conventional methods require that all possible recovery paths be pre-defined and stored in advance, considering various combinations of FTSVs and RTSVs. As the number of FTSVs and RTSVs increases, the logic design area for managing these configurations also increases, leading to exponential growth in complexity.

In contrast, the present invention utilizes a simplified path configuration mechanism that requires only a one-time setup. Once configured, the path remains valid without further modification, regardless of how many FTSVs occur within the same TSV group. Therefore, the present invention eliminates complexity growth even in the presence of multiple FTSVs in a single group.

From the perspective of the clustered FTSV Tolerance(\textcircled{2}), In conventional methods, recovery becomes infeasible when the number of FTSVs in a single TSV group exceeds the number of available RTSVs. However, the present invention allows recovery even if all TSVs (e.g., 128) within a single TSV group are identified as faulty. This demonstrates the superior fault-tolerance of the proposed method when dealing with clustered FTSVs.

From the perspective of the Clock Synchronization(\textcircled{3}), In conventional approaches, the routers (e.g., MUXs) used to bypass FTSVs are typically placed between the TSV groups and the high bandwidth memory dies. This positioning complicates clock synchronization, resulting in additional delay time. Prior studies have shown that such configurations can introduce clock delays of up to 40 picoseconds when repairing FTSVs. In contrast, the present invention places the bypassing MUXs within the logic control region of the base die, where clock control is readily available. This architecture enables clock synchronization and eliminates the delay time that would otherwise be introduced during FTSV repair.

The present invention proposes a method to address the yield degradation problem of high bandwidth memory (HBM) caused by faulty through-silicon vias (FTSVs).

Conventional techniques generally rely on allocating a small number of redundant TSVs (RTSVs) within each TSV group. When an FTSV is detected, the system bypasses the defective TSV by rerouting signals through one of the preconfigured RTSVs. However, such methods suffer from significant limitations. Since multiple FTSVs may occur within a single TSV group and the fault cases can vary widely, it is practically infeasible to predefine all possible recovery paths. Furthermore, if the number of FTSVs exceeds the number of RTSVs available within the same group, recovery becomes impossible.

In contrast, the present invention does not merely supplement existing TSV groups with additional RTSVs. Instead, it introduces a new paradigm that bypasses the entire faulty memory die associated with the defective TSV group. To implement this approach, a redundant memory die and one dedicated TSV group for RTSV use must be provisioned.

FTSV information identified during the built-in self-test (TBIST) process is stored in non-volatile memory (NVM). The proposed method implements a multiplexer (MUX) control algorithm in the logic control region of the base die. When an FTSV is detected, the connection between the data I/O bus channel and the corresponding faulty TSV group is disconnected. The memory die associated with the faulty TSV group is excluded from operation, and instead, the data I/O bus channel is reconnected to the RTSV group, allowing access to the Redundant Memory die.

Although the present invention requires one additional HBM die, it offers significant advantages over conventional methods. It minimizes architectural complexity, robustly tolerates clustered FTSVs, supports clock synchronization, and introduces no additional delay time. Therefore, the proposed method provides a highly reliable and efficient FTSV repair solution and represents a breakthrough in improving HBM yield.

While the preferred embodiments of the present invention have been described with reference to the accompanying drawings, it is to be understood that modifications and variations may be made by those skilled in the art without departing from the spirit or scope of the invention. For example, the material or size of each component may be changed depending on the application, or multiple disclosed embodiments may be combined or replaced. Such modifications also fall within the scope of the present invention as defined in the claims.
100 Apparatus for High Bandwidth Memory
110 A plurality of High Bandwidth Memory Dies
120 A plurality of Through Silicon Vias
130 Memory Controller Module
132 2-Channel Multiplexer
134 I/O (Input/Output) Channe
140 Test Module
150 Non-Volatile Memory

What is claimed is:

1. An apparatus for high bandwidth memory (HBM), comprising:
a plurality of high bandwidth memory dies (HBM dies);
a plurality of through-silicon vias (TSVs), each corresponding one-to-one to the plurality of HBM dies;
a memory controller module configured to control connections between the plurality of HBM dies and the plurality of TSVs;
a test module configured to detect faults in the plurality of HBM dies and the plurality of TSVs; and
a non-volatile memory configured to store fault locations of at least one faulty HBM die and at least one faulty TSV detected by the test module,
wherein the memory controller module is configured to establish connections to the TSVs corresponding to the fault locations stored in the non-volatile memory.

2. The apparatus of claim 1, wherein said test module is configured to operate when the apparatus is booted up, operate periodically at predefined time intervals, or operate in response to a control command, and to store fault locations of the HBM dies and the TSVs in the non-volatile memory based on the outcome of the test module operation.

3. The apparatus of claim 1, wherein the memory controller module is configured to operate when the apparatus is booted up, periodically at predetermined intervals, or in response to an operation command,
and, when a TSV corresponding to a fault location stored in the non-volatile memory is present, to set an operation for the TSV corresponding to the fault location.

4. The apparatus of claim 1, wherein said memory controller module is configured to isolate the TSV corresponding to the fault location stored in the non-volatile memory so as to exclude it from operation, and the apparatus for high bandwidth memory operates excluding the corresponding TSV based on the setting by the memory controller module.

5. The apparatus of claim 4, wherein said memory controller module is configured to set at least one TSV corresponding to the fault location stored in the non-volatile memory to be excluded either by turning off power to the TSV in hardware, or by making the corresponding TSV inactive in software as if it does not exist.

6. The apparatus of claim 1, wherein said memory controller module is configured to exclude all HBM dies and TSVs corresponding to the fault locations stored in the non-volatile memory from operation when they are multiple.

7. The apparatus of claim 1, wherein said non-volatile memory includes information on the plurality of HBM dies and the TSVs corresponding respectively to each of the HBM dies, includes individual information on each HBM die and corresponding TSV, and includes information indicating the number of faults for each faulty TSV.

8. The apparatus of claim 1, wherein said test module includes a Memory Built-In Self-Test (MBIST) module.

9. The apparatus of claim 1, wherein said apparatus further comprises at least one redundant HBM die and the same number of redundant TSVs corresponding one-to-one to the at least one redundant HBM die.

10. The apparatus of claim 9, wherein said memory controller module is configured to isolate at least one TSV corresponding to the fault location stored in the non-volatile memory so as to exclude it from operation of the apparatus,
and to connect the same number of TSVs from among the redundant TSVs in place of the excluded TSVs so as to include them in the operation of the apparatus.

11. The apparatus of claim 9, wherein said memory controller module is connected to the TSVs in the following order—an I/O channel, a 2-channel multiplexer, a TSV, and an HBM die.

12. The apparatus of claim 11, wherein the connection to the TSV of the 2-channel multiplexer is reconfigured under the control of said memory controller module.

13. The apparatus of claim 12, wherein the connection to the TSV of the 2-channel multiplexer is reconfigured in response to a control signal applied to the 2-channel multiplexer.

14. The apparatus of claim 9, wherein, when one redundant high bandwidth memory die and one redundant TSV corresponding one-to-one to the redundant high bandwidth memory die are provided,
said memory controller module is configured to disconnect the connection to the TSV at the fault location in the corresponding 2-channel multiplexer stored in the non-volatile memory,
sequentially connect to the next TSV,
and connect to the one redundant TSV in the final 2-channel multiplexer.

15. The apparatus of claim 14, wherein, when a plurality of TSVs corresponding to fault locations stored in the non-volatile memory are present,
said memory controller module is configured to disconnect and exclude from operation the TSVs corresponding to more than one of the detected fault locations, and is configured to operate while excluding the corresponding TSVs.

16. The apparatus of claim 9, wherein, when a plurality of redundant high bandwidth memory dies and a corresponding plurality of redundant TSVs, each in a one-to-one correspondence with the redundant high bandwidth memory dies, are provided, said memory controller module is configured to sequentially disconnect connections to a plurality of TSVs corresponding to fault locations stored in the non-volatile memory in the respective 2-channel multiplexers,
to sequentially connect to subsequent TSVs,
and to connect, in the final 2-channel multiplexer, to the plurality of redundant TSVs.

17. The apparatus of claim 16, wherein, when the number of TSVs corresponding to fault locations stored in the non-volatile memory exceeds the number of the plurality of redundant TSVs,
said memory controller module is configured to disconnect and exclude from operation the TSVs corresponding to the fault locations that exceed the plurality of redundant TSVs,
and is configured to operate while excluding the corresponding TSVs.

18. The apparatus of claim 11, wherein said 2-channel multiplexer is configured to connect to either a first channel or a second channel based on an input signal.

19. The apparatus of claim 18, wherein said 2-channel multiplexer is configured to connect to either the first channel or the second channel in both forward and reverse operation modes, based on an input signal.
